(19) United States
(12) Patent Application Publication
(10) Pub. No.: US 2026/0143730 A1
(43) Pub. Date: May 21, 2026

(54) SEMICONDUCTOR DEVICE AND METHOD FOR MANUFACTURING SEMICONDUCTOR DEVICE

(71) Applicant: TOYODA GOSEI CO., LTD., Kiyosu-shi (JP)

(72) Inventors: Kota YASUNISHI, Kiyosu-shi (JP); Nariaki TANAKA, Kiyosu-shi (JP)

(21) Appl. No.: 19/388,197

(22) Filed: Nov. 13, 2025

(30) Foreign Application Priority Data
Nov. 20, 2024 (JP) 2024-202655

(51) Int. Cl. H10D 30/01; H10D 30/66; H10D 62/85

(52) U.S. Cl. CPC H10D 30/0297; H10D 30/668; H10D 62/8503

(57) ABSTRACT

A method for manufacturing a semiconductor device, includes: forming, by a formation method using a raw material and a carrier gas that contain hydrogen, a p-type layer containing a Group III nitride semiconductor doped with a p-type impurity; performing an annealing treatment in a state, where at least a region of a surface of the p-type layer that contributes to an operation of the device is exposed, to activate the p-type impurity in the p-type layer; and forming an n-type layer containing an n-type Group III nitride semiconductor over the p-type layer by a formation method using a raw material and a carrier gas that contain no hydrogen.

### CROSS-REFERENCE TO RELATED APPLICATION

This application is based on and claims priority under 35 USC 119 from Japanese Patent Application No. 2024-202655 filed on Nov. 20, 2024.

### TECHNICAL FIELD

The present invention relates to a semiconductor device and a method for manufacturing the semiconductor device.

### BACKGROUND ART

It is widely known that Mg is used as a p-type impurity for a Group III nitride semiconductor. Simply forming an Mg-doped Group III nitride semiconductor is not sufficient to obtain a p-type semiconductor, because Mg atoms bond with H atoms, which inhibits the activation of Mg. Therefore, after the Mg-doped Group III nitride semiconductor is formed, an annealing treatment is performed to dissociate Mg—H bonds and remove hydrogen from a semiconductor layer, thereby implementing p-type conductivity.

In this method of implementing the p-type conductivity, in a case of a structure in which an n-type layer is stacked on a p-type layer, it is difficult to implement the p-type conductivity in the p-type layer. This is because a surface of the p-type layer is covered with the n-type layer, which inhibits removal of hydrogen from a p-type semiconductor layer.

Patent Literature 1 describes that after a first n-type layer, a p-type layer, and a second n-type layer are formed in this order, a trench is formed to expose the p-type layer on a side surface of the trench, and then an annealing treatment is performed to remove hydrogen from the p-type layer exposed on the side surface of the trench.
Patent Literature 1: JP2003-68745A

### SUMMARY OF INVENTION

However, in the method of Patent Literature 1, an area of the p-type layer exposed on the side surface of the trench is small, and the amount of hydrogen removed is small. Therefore, the activation of Mg becomes insufficient.

The present invention has been made in view of such a background, and an object thereof is to provide a semiconductor device having a high activation rate of a p-type impurity, and a method for manufacturing the same.

One aspect of the present invention is
a method for manufacturing a semiconductor device, including:
a p-type layer formation step of forming, by a formation method using a raw material and a carrier gas that contain hydrogen, a p-type layer made of a Group III nitride semiconductor doped with a p-type impurity;
an annealing treatment step of performing an annealing treatment in a state, where at least a region of a surface of the p-type layer that contributes to an operation of the device is exposed, to activate the p-type impurity in the p-type layer; and
an n-type layer formation step of forming an n-type layer made of an n-type Group III nitride semiconductor on the p-type layer by a formation method using a raw material and a carrier gas that contain no hydrogen.

Another aspect of the present invention is
a semiconductor device including:
a first n-type layer made of an n-type Group III nitride semiconductor;
a p-type layer formed on the first n-type layer and made of a p-type Group III nitride semiconductor; and
a second n-type layer formed on the p-type layer and made of an n-type Group III nitride semiconductor, in which
an H concentration is 10% or less of a p-type impurity concentration in the p-type layer.

In the above-described aspect, the annealing treatment is performed in the state where at least the region of the surface of the p-type layer that contributes to the operation of the device is exposed, and hydrogen can be efficiently removed from the p-type layer. In addition, since the n-type layer is formed by the formation method using a raw material and a carrier gas that contain no hydrogen (i.e., using a raw material containing no hydrogen and a carrier gas containing no hydrogen), it is possible to prevent the p-type impurity from being inactivated again due to the mixing of hydrogen into the p-type layer. Therefore, even when the n-type layer is formed on the p-type layer, the activation rate of the p-type impurity in the p-type layer can be improved.

As described above, according to the above-described aspects, it is possible to provide a semiconductor device having a high activation rate of a p-type impurity, and a method for manufacturing the same.

### BRIEF DESCRIPTION OF DRAWINGS

FIG. 1 is a cross-sectional view illustrating a configuration of a semiconductor device according to a first embodiment, which is a cross-sectional view perpendicular to a main surface of a substrate.

FIG. 2 is a flowchart illustrating a method for manufacturing the semiconductor device according to the first embodiment.

FIG. 3 is a cross-sectional view illustrating a structure in a step of a manufacturing process of the semiconductor device according to the first embodiment, which is a cross-sectional view perpendicular to the main surface of the substrate.

FIG. 4 is a cross-sectional view illustrating a structure in a step of the manufacturing process of the semiconductor device according to the first embodiment, which is a cross-sectional view perpendicular to the main surface of the substrate.

FIG. 5 is a cross-sectional view illustrating a structure in a step of the manufacturing process of the semiconductor device according to the first embodiment, which is a cross-sectional view perpendicular to the main surface of the substrate.

FIG. 6 is a cross-sectional view illustrating a structure in a step of the manufacturing process of the semiconductor device according to the first embodiment, which is a cross-sectional view perpendicular to the main surface of the substrate.

FIG. 7 is a graph illustrating distributions of impurity concentrations in a depth direction.

### DESCRIPTION OF EMBODIMENTS

A method for manufacturing a semiconductor device includes: a p-type layer formation step of forming, by a formation method using a raw material and a carrier gas that contain hydrogen, a p-type layer made of a Group III nitride semiconductor doped with a p-type impurity; an annealing treatment step of performing an annealing treatment in a state, where at least a region of a surface of the p-type layer that contributes to an operation of the device is exposed, to activate the p-type impurity in the p-type layer; and an n-type layer formation step of forming an n-type layer made of an n-type Group III nitride semiconductor on the p-type layer by a formation method using a raw material and a carrier gas that contain no hydrogen.

In the above-described method for manufacturing a semiconductor device, the formation method using a raw material and a carrier gas that contain no hydrogen may be sputtering or MBE.

In the above-described method for manufacturing a semiconductor device, the semiconductor device may be a MOSFET that has a trench gate structure having a body electrode on a region of the p-type layer, and the annealing treatment may be performed in a state where at least a region near side surfaces of a trench and a formation region of the body electrode are exposed, both regions being on the surface of the p-type layer.

In the method for manufacturing a semiconductor device, the annealing treatment may be performed in a state where 90% or more of the surface of the p-type layer is exposed. Hydrogen can be more efficiently removed from the p-type layer.

In the method for manufacturing a semiconductor device, the annealing treatment may be performed in a state where an entire surface of the p-type layer is exposed. Hydrogen can be further efficiently removed from the p-type layer.

In the method for manufacturing a semiconductor device, in the annealing treatment, a heat treatment temperature may be set to 700° C. or more and 900° C. or less, and a heat treatment time may be set to 5 minutes to 60 minutes.

In the method for manufacturing a semiconductor device, in the annealing treatment, an annealing atmosphere may be a mixed gas atmosphere of nitrogen and oxygen. In this case, a ratio of an oxygen flow rate to a nitrogen flow rate may be set to 1% or more. An activation rate of the p-type impurity can be further improved.

In the method for manufacturing a semiconductor device, the p-type impurity may be Mg.

A semiconductor device includes: a first n-type layer made of an n-type Group III nitride semiconductor; a p-type layer formed on the first n-type layer and made of a p-type Group III nitride semiconductor; and a second n-type layer formed on the p-type layer and made of an n-type Group III nitride semiconductor, in which an H concentration is 10% or less of a p-type impurity concentration in the p-type layer.

In the above-described semiconductor device, the p-type impurity concentration in the p-type layer may be 1×10¹⁸/cm³ or more and 1×10²⁰/cm³ or less.

### First Embodiment

### 1. Configuration of Semiconductor Device

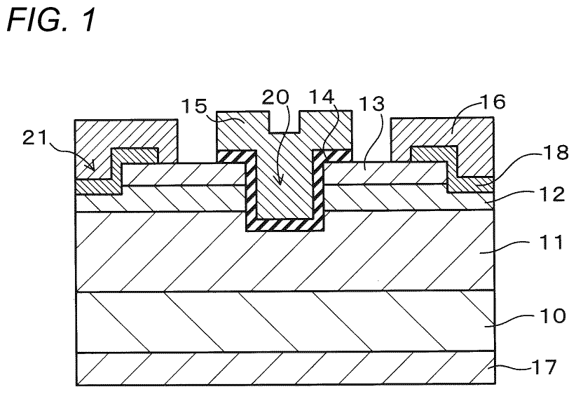

FIG. 1 is a view illustrating the configuration of the semiconductor device according to the first embodiment. The semiconductor device according to the first embodiment is a vertical MOSFET having a trench gate structure, and includes a substrate 10, a first n-type layer 11, a p-type layer 12, a second n-type layer 13, a gate insulating film 14, a gate electrode 15, a source electrode 16, a drain electrode 17, and a body electrode 18 as illustrated in FIG. 1.

The substrate 10 is made of Si-doped n⁺-GaN having a c-plane as a main surface. A Si concentration in the substrate 10 is 1×10¹⁸/cm³ or more. A material of the substrate 10 may be a material other than GaN, and any material can be used as long as the material can grow a Group III nitride semiconductor and has conductivity. For example, Si, SiC, ZnO, or the like can be used.

The first n-type layer 11 is provided on the substrate 10. The first n-type layer 11 is made of Si-doped n⁻-GaN. A thickness of the first n-type layer 11 is 8 μm to 15 μm. In addition, a Si concentration in the first n-type layer 11 is 1×10¹⁵/cm³ to 5×10¹⁶/cm³. As an n-type impurity, O, Ge, or the like may be used instead of or in addition to Si.

The p-type layer 12 is provided on the first n-type layer 11. The p-type layer 12 is made of Mg-doped p-GaN. A thickness of the p-type layer 12 is 0.1 μm to 1 μm. An Mg concentration in the p-type layer 12 is 1×10¹⁸/cm³ to 8×10²⁰/cm³. As a p-type impurity, Zn or the like may be used instead of or in addition to Mg. An H concentration in the p-type layer 12 is 10% or less of the Mg concentration. Therefore, an Mg activation rate in the p-type layer 12 is large, and the p-type layer 12 is sufficiently activated. More preferably, the H concentration 12 is 5% or less, and further preferably 2% or less of the Mg concentration in the p-type layer.

A Si concentration at an interface between the first n-type layer 11 and the p-type layer 12 is preferably 10 times or less the Si concentration (an average in a thickness direction) in the first n-type layer 11. It is possible to prevent Si at the interface between the first n-type layer 11 and the p-type layer 12 from causing deterioration in characteristics or deterioration in stability of the characteristics of the semiconductor device. More preferably, the Si concentration at the interface between the first n-type layer 11 and the p-type layer 12 is 5 times or less the Si concentration in the first n-type layer 11.

The second n-type layer 13 is provided on the p-type layer 12. The second n-type layer 13 is made of Si-doped n⁺-GaN. A thickness of the second n-type layer 13 is 0.1 μm to 0.5 μm. In addition, a Si concentration in the second n-type layer 13 is 1×10¹⁸/cm³ to 1×10¹⁹/cm³.

A trench 20 is formed in a region of a surface of the second n-type layer 13. The trench 20 has a depth sufficient to penetrate through the second n-type layer 13 and the p-type layer 12 and reach the first n-type layer 11. The first n-type layer 11 is exposed at a bottom surface of the trench 20. In addition, the first n-type layer 11, the p-type layer 12, and the second n-type layer 13 are exposed at each of side surfaces of the trench 20 in this order from a bottom surface side.

A recess 21 is provided in a region of the second n-type layer 13 that is different from a formation region of the trench 20. The recess 21 is a groove having a depth sufficient to penetrate through the second n-type layer 13 and reach the p-type layer 12.

The gate insulating film 14 is continuously provided over a bottom surface, side surfaces, and a top surface (a region on a surface of the second n-type layer 13 that is near the trench 20) of the trench 20. The gate insulating film 14 is made of SiO₂, for example.

The gate electrode 15 is provided across the bottom surface, the side surfaces, and the top surface of the trench 20 via the gate insulating film 14. The gate electrode 15 is made of TiN, for example.

The body electrode 18 is provided continuously over a bottom surface, side surfaces, and a top surface (a region on a surface of the second n-type layer 13 that is near the recess 21) of the recess 21. The body electrode 18 is made of Ni, for example.

The source electrode 16 is provided on the second n-type layer 13 and the body electrode 18. The source electrode 16 is made of Pd/Al/Ti, for example.

The drain electrode 17 is provided on a back surface of the substrate 10. The drain electrode 17 is made of Pd/Al/Ti, for example.

### 2. Method for Manufacturing Semiconductor Device

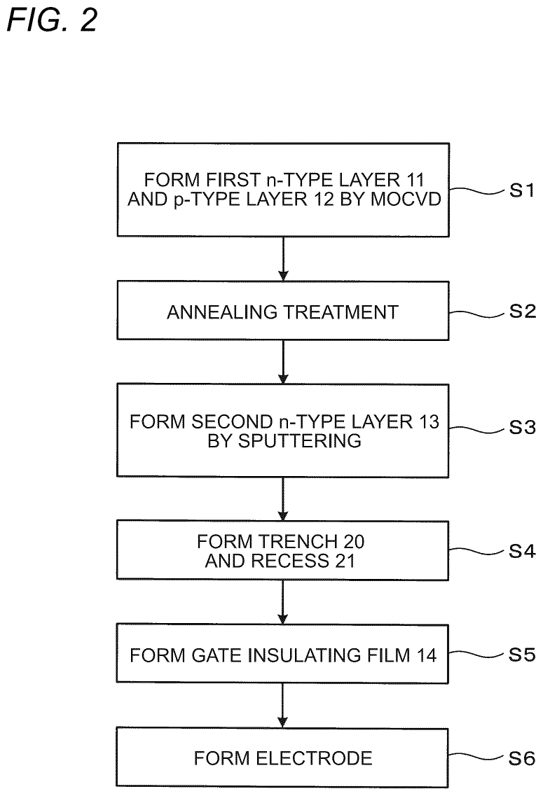

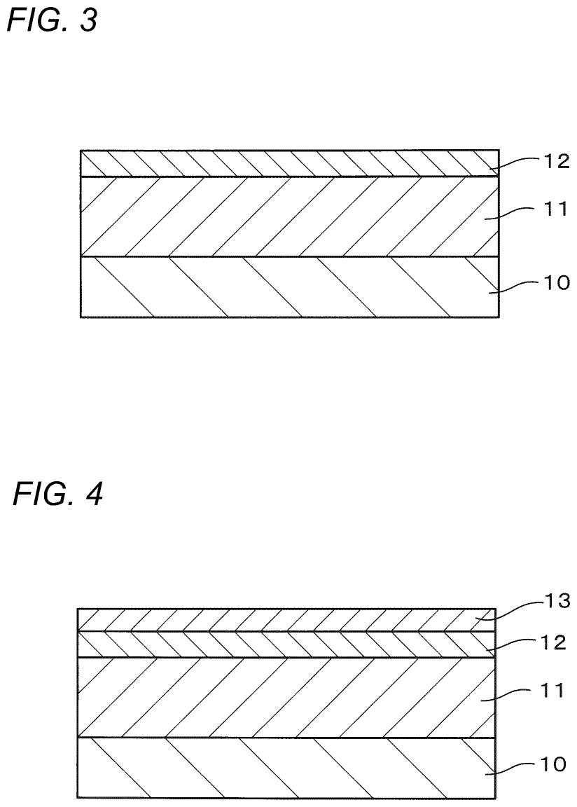

Next, the method for manufacturing the semiconductor device according to the first embodiment will be described with reference to FIGS. 2 to 6. FIG. 2 is a flowchart illustrating a manufacturing process of the semiconductor device according to the first embodiment, and FIGS. 3 to 6 are each a cross-sectional view illustrating a structure in a step among steps of the manufacturing process of the semiconductor device according to the first embodiment, which is a cross-sectional view perpendicular to the main surface of the substrate.

First, the first n-type layer 11 and the p-type layer 12 are formed on the substrate 10 in this order from a substrate 10 side by MOCVD (step S1 in FIG. 2, see FIG. 3). TMGa (trimethylgallium) is used as a Ga source gas, and ammonia is used as an N source gas. A mixed gas of hydrogen and nitrogen is used as a carrier gas. Silane is used as an n-type dopant gas, and biscyclopentadienyl magnesium is used as a p-type dopant gas.

Here, the first n-type layer 11 and the p-type layer 12 are continuously grown using the same MOCVD. Reasons are as follows. When the first n-type layer 11 and the p-type layer 12 are not continuously grown, the first n-type layer 11 may be exposed to the atmosphere. When the first n-type layer 11 is exposed to the atmosphere, a large amount of Si adheres to a surface of the first n-type layer 11. Accordingly, a Si layer is formed at the interface between the first n-type layer 11 and the p-type layer 12, which causes deterioration in characteristics or deterioration in stability of the characteristics of the semiconductor device. Therefore, by continuously growing the first n-type layer 11 and the p-type layer 12, the first n-type layer 11 is prevented from being exposed to the atmosphere.

A reason why the first n-type layer 11 and the p-type layer 12 are formed not by sputtering but by MOCVD is that it is necessary to form the first n-type layer 11 thickly in order to improve a breakdown voltage of the device, and the MOCVD is superior to sputtering in terms of a growth rate and mass productivity. A formation method other than the MOCVD, which uses a raw material and a carrier gas that contain hydrogen, may be used. For example, HVPE is used.

Next, an annealing treatment is performed (step S2). This annealing treatment breaks bonds between Mg (magnesium) and H (hydrogen) in the p-type layer 12 and removes H from the p-type layer 12. Here, since the annealing treatment is performed before the second n-type layer 13 is formed, an entire surface of the p-type layer 12 is exposed. Therefore, an exposed area of the p-type layer 12 is large, and H can be efficiently removed from the p-type layer 12.

A heat treatment temperature of the annealing treatment is preferably 700° C. to 900° C., and a heat treatment time is preferably 5 to 60 minutes. The higher the heat treatment temperature and the longer the heat treatment time, the higher the effect of removing H from the p-type layer 12. On the other hand, when the heat treatment temperature is too high or the heat treatment time is too long, thermal decomposition of GaN occurs, which causes deterioration of the crystal quality of the p-type layer 12 or an increase in surface roughness. Therefore, by setting the heat treatment temperature and the heat treatment time of the annealing treatment within the above-described ranges, a balance between these advantages and disadvantages can be optimized. That is, the Mg activation rate can be sufficiently improved while maintaining the crystallinity of the p-type layer 12.

The annealing atmosphere is preferably atmospheric pressure. Specifically, the pressure is preferably 0.9 atm to 1.1 atm. Within this range, H can be effectively removed from the p-type layer 12.

The annealing atmosphere may be a mixed gas atmosphere of nitrogen and oxygen. The Mg activation rate can be improved by adding oxygen to nitrogen. A ratio of an oxygen flow rate to a nitrogen flow rate is preferably 1% or more, more preferably 2% or more, and still more preferably 5% or more. It is considered that a reason why the Mg activation rate is improved by adding oxygen to nitrogen is that hydrogen and oxygen easily react with each other, and thus when oxygen is mixed with hydrogen, hydrogen reacts with hydrogen to improve the effect of removing hydrogen from the p-type layer 12. Although there is no upper limit to the ratio of the oxygen flow rate to the nitrogen flow rate, an effect of improving the Mg activation rate saturates when the ratio exceeds 5%.

Next, the second n-type layer 13 is formed on the p-type layer 12 by sputtering (step S3, see FIG. 4). For example, the second n-type layer 13 is formed by magnetron sputtering using a sintered GaN body as a target. Alternatively, the second n-type layer 13 may be formed by RF sputtering or the like.

Since a formation method of the second n-type layer 13 is sputtering, a material containing H is not used as a raw material or a carrier gas. Therefore, H does not enter the p-type layer 12 at the time of forming the second n-type layer 13, and thus Mg in the p-type layer 12 can be prevented from being inactivated again.

The formation method of the second n-type layer 13 may be a method other than sputtering as long as the method uses a material gas and a carrier gas that do not contain H. For example, the second n-type layer 13 may be formed by molecular beam epitaxy (MBE).

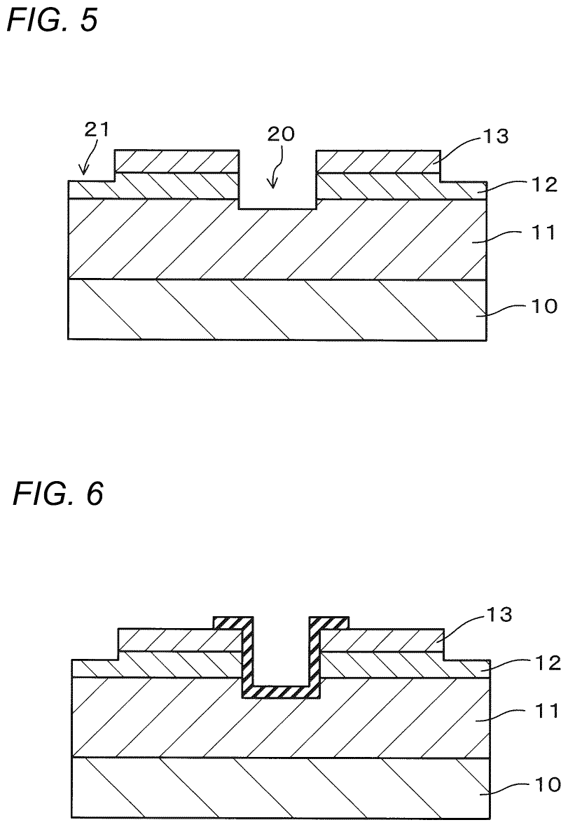

Next, a predetermined region of the second n-type layer 13 is dry-etched until reaching the first n-type layer 11 to form the trench 20. Next, a predetermined region of the second n-type layer 13 is dry-etched until reaching the p-type layer 12 to form the recess 21 (step S4, see FIG. 5). The recess 21 may be formed first, and then the trench 20 may be formed. Here, since the annealing treatment for p-type conductivity is performed before the trench 20 is formed, the p-type layer 12 exposed on the side surfaces of the trench 20 is not roughened by the annealing treatment. The p-type layer 12 on the side surfaces of the trench 20 is a region serving as a channel, and therefore, when the p-type layer 12 is roughened, the characteristics of the MOSFET are deteriorated. However, according to the first embodiment, the p-type layer 12 on the side surfaces of the trench 20 is not roughened, and therefore, the characteristics of the MOSFET are not deteriorated.

Next, the gate insulating film 14 is continuously formed over the bottom surface, the side surfaces, and the top surface of the trench 20 by ALD (step S5, see FIG. 6).

Next, the gate electrode 15 is formed on the bottom surface, the side surfaces, and the upper surface of the trench 20 via the gate insulating film 14 by vapor deposition or sputtering. Next, the body electrode 18 is formed continuously on the bottom surface, the side surfaces, and the top surface of the recess 21, and the source electrode 16 is formed on the second n-type layer 13 and the body electrode 18. Next, the drain electrode 17 is formed on the back surface of the substrate 10. The body electrode 18, the source electrode 16, and the drain electrode 17 are formed by vapor deposition or sputtering, and are patterned by lifting off. Thus, the semiconductor device according to the first embodiment is manufactured.

As described above, according to the method for manufacturing a semiconductor device according to the first embodiment, even in the structure in which the second n-type layer 13 is provided on the p-type layer 12, the activation rate of the p-type impurity in the p-type layer 12 can be increased.

### 3. Experiment Results

Next, the experiment results regarding the semiconductor device according to the first embodiment will be described. Three types of samples of Example 1 and Comparative Examples 1 and 2 were fabricated as follows.

The sample of Example 1 was fabricated as follows. First, the first n-type layer 11 made of n-GaN and the p-type layer 12 made of p-GaN were formed on the substrate 10 in this order from the substrate 10 side by MOCVD. Then, the annealing treatment was performed. Next, the second n-type layer 13 made of n-GaN was formed by sputtering. The sample of Example 1 was fabricated as described above.

The sample of Comparative Example 1 was fabricated as follows. First, the first n-type layer 11 made of n-GaN, the p-type layer 12 made of p-GaN, and the second n-type layer 13 made of n-GaN were formed on the substrate 10 in this order from the substrate 10 side by MOCVD. Next, the trench 20 was formed in the surface of the second n-type layer 13. The trench 20 had a depth sufficient to reach the first n-type layer 11. Next, the annealing treatment was performed. Annealing conditions were the same as in Example 1. The sample of Comparative Example 1 was fabricated as described above.

The sample of Comparative Example 2 was fabricated as follows. First, the first n-type layer 11 made of n-GaN and the p-type layer 12 made of p-GaN were formed on the substrate 10 in this order from the substrate 10 side by MOCVD. Next, the annealing treatment was performed. The annealing conditions were the same as in Example 1. Next, the second n-type layer 13 made of n-GaN was formed by MOCVD. The sample of Comparative Example 2 was fabricated as described above.

The Mg concentration and the H concentration in the p-type layer 12 were measured for each of the samples of Example 1 and Comparative Examples 1 and 2. Table 1 summarizes the Mg concentration, the H concentration, and an N/Mg ratio in the p-type layer 12 for each of the samples of Example 1 and Comparative Example 1, 2. The H/Mg ratio is a ratio of the H concentration to the Mg concentration.

TABLE 1

| | Impurity concentration in p-type layer 12 | | |
|---|---|---|---|
| | Mg concentration | H concentration | H/Mg |
| | (/cm³) | (/cm³) | ratio (%) |
| Comparative | 5.0 × 10¹⁸ | 3.9 × 10¹⁸ | 78.4 |
| Example 1 | | | |
| Comparative | 4.0 × 10¹⁸ | 1.1 × 10¹⁸ | 27.0 |
| Example 2 | | | |
| Example 1 | 4.6 × 10¹⁸ | 6.4 × 10¹⁶ | 1.4 |

As illustrated in Table 1, in Example 1, the H/Mg ratio was 1.4%, indicating that a large amount of H was removed from the p-type layer 12. It is considered that this is due to the following reasons: the annealing treatment is performed after the p-type layer 12 is formed and before the second n-type layer 13 is formed, the surface of the p-type layer 12 is largely exposed, the second n-type layer 13 is formed by sputtering, and thus H does not enter the p-type layer 12 again.

On the other hand, in Comparative Example 1, the H/Mg ratio was 78.4%, indicating that not much of H was removed from the p-type layer 12. This is considered to be because an area of the p-type layer 12 exposed on the side surfaces of the trench 20 is small.

In addition, in Comparative Example 2, the H/Mg ratio is 27.0%, indicating that more H is removed from the p-type layer 12 than in Comparative Example 1, but the amount of H removed is smaller than in Example 1. This is considered to be because H enters the p-type layer 12 again since the second n-type layer 13 is formed by the MOCVD.

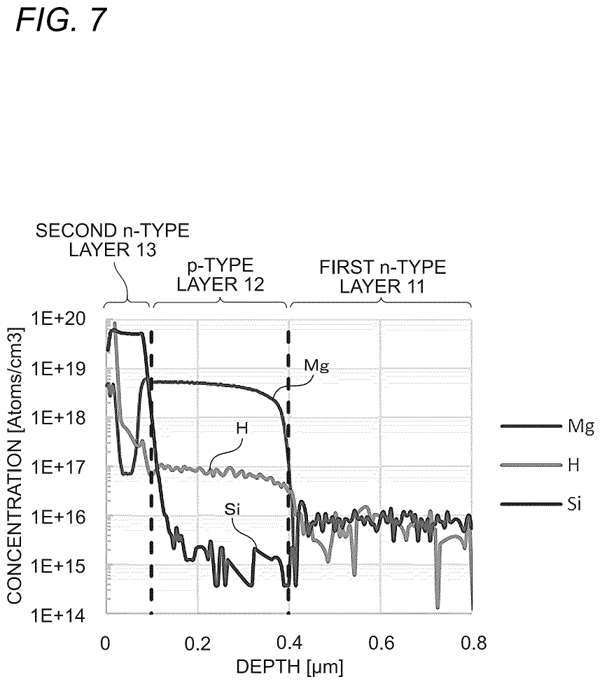

Further, for the sample of Example 1, distributions of impurity concentrations in a depth direction were measured. The measured impurities are Mg, H, and Si. As illustrated in FIG. 7, the Mg concentration and the H concentration in the p-type layer 12 were approximately uniform in the thickness direction, and the H concentration was about two orders of magnitude lower than the Mg concentration. Therefore, it was confirmed that H in the p-type layer 12 was efficiently removed. An average Si concentration (average in the thickness direction) in the first n-type layer 11 was about 1×10¹⁶/cm³, whereas the Si concentration in the vicinity of the interface between the first n-type layer 11 and the p-type layer 12 was about 2×10¹⁶/cm³, and no increase in Si concentration was observed in the vicinity of the interface between the first n-type layer 11 and the p-type layer 12. That is, since the first n-type layer 11 and the p-type layer 12 were continuously grown, it was confirmed that the surface of the first n-type layer 11 was not contaminated with Si.

### Modification of First Embodiment

The semiconductor device according to the first embodiment is the MOSFET having the trench gate structure, but the present invention can be applied to any semiconductor device as long as the semiconductor device has a structure having an n-type layer or a non-doped layer on a p-type layer. For example, the present invention can also be applied to bipolar transistors and IGBTs.

In the semiconductor device according to the first embodiment, each semiconductor layer is made of GaN, but the present invention is not limited to GaN and can be applied to any Group III nitride semiconductor.

In the method for manufacturing the semiconductor device according to the first embodiment, the entire surface of the p-type layer 12 is exposed during the annealing treatment, but the surface of the p-type layer 12 other than a region contributing to the operation of the device may be covered with an insulating film or the like. In a case of the semiconductor device according to the first embodiment, the region contributing to the operation of the device is specifically a region near the side surfaces of the trench 20 and a region corresponding to a lower portion of the body electrode 18. For example, the surface of the p-type layer 12 may not be exposed in a region where the trench 20 is formed in a subsequent step, a region at an outer periphery of the device, and the like. Preferably, 90% or more of the surface of the p-type layer 12 is exposed, and most preferably, the entire surface of the p-type layer 12 is exposed.

### REFERENCE SIGNS LIST

10: substrate
11: first n-type layer
12: p-type layer
13: second n-type layer
14: gate insulating film
15: gate electrode
16: source electrode
17: drain electrode
18: body electrode
20: trench
21: recess

What is claimed is:

1. A method for manufacturing a semiconductor device, comprising:
forming, by a formation method using a raw material and a carrier gas that contain hydrogen, a p-type layer comprising a Group III nitride semiconductor doped with a p-type impurity;
performing an annealing treatment in a state, where at least a region of a surface of the p-type layer that contributes to an operation of the device is exposed, to activate the p-type impurity in the p-type layer; and
forming an n-type layer comprising an n-type Group III nitride semiconductor over the p-type layer by a formation method using a raw material and a carrier gas that contain no hydrogen.

2. The method for manufacturing a semiconductor device according to claim 1, wherein
the formation method using the raw material and the carrier gas that contain no hydrogen is sputtering.

3. The method for manufacturing a semiconductor device according to claim 1, wherein
the formation method using the raw material and the carrier gas that contain no hydrogen is a molecular beam epitaxy method.

4. The method for manufacturing a semiconductor device according to claim 1, wherein
the semiconductor device is a MOSFET that has a trench gate structure having a body electrode on a region of the p-type layer, and
the annealing treatment is performed in a state where at least: a region of the surface of the p-type layer near side surfaces of a trench; and a region of the surface of the p-type layer on which the body electrode is formed are exposed.

5. The method for manufacturing a semiconductor device according to claim 2, wherein
the semiconductor device is a MOSFET that has a trench gate structure having a body electrode on a region of the p-type layer, and
the annealing treatment is performed in a state where at least: a region of the surface of the p-type layer near side surfaces of a trench; and a region of the surface of the p-type layer on which the body electrode is formed are exposed.

6. The method for manufacturing a semiconductor device according to claim 3, wherein
the semiconductor device is a MOSFET that has a trench gate structure having a body electrode on a region of the p-type layer, and
the annealing treatment is performed in a state where at least: a region of the surface of the p-type layer near side surfaces of a trench; and a region of the surface of the p-type layer on which the body electrode is formed are exposed.

7. The method for manufacturing a semiconductor device according to claim 1, wherein
the annealing treatment is performed in a state where 90% or more of the surface of the p-type layer is exposed.

8. The method for manufacturing a semiconductor device according to claim 2, wherein
the annealing treatment is performed in a state where 90% or more of the surface of the p-type layer is exposed.

9. The method for manufacturing a semiconductor device according to claim 3, wherein
the annealing treatment is performed in a state where 90% or more of the surface of the p-type layer is exposed.

10. The method for manufacturing a semiconductor device according to claim 7, wherein
the annealing treatment is performed in a state where an entire surface of the p-type layer is exposed.

11. The method for manufacturing a semiconductor device according to claim 8, wherein
the annealing treatment is performed in a state where an entire surface of the p-type layer is exposed.

12. The method for manufacturing a semiconductor device according to claim 9, wherein
the annealing treatment is performed in a state where an entire surface of the p-type layer is exposed.

13. The method for manufacturing a semiconductor device according to claim 1, wherein
in the annealing treatment, a heat treatment temperature is set to 700° C. or more and 900° C. or less, and a heat treatment time is set to 5 minutes to 60 minutes.

14. The method for manufacturing a semiconductor device according to claim 2, wherein
in the annealing treatment, a heat treatment temperature is set to 700° C. or more and 900° C. or less, and a heat treatment time is set to 5 minutes to 60 minutes.

15. The method for manufacturing a semiconductor device according to claim 3, wherein
in the annealing treatment, a heat treatment temperature is set to 700° C. or more and 900° C. or less, and a heat treatment time is set to 5 minutes to 60 minutes.

16. The method for manufacturing a semiconductor device according to claim 1, wherein
in the annealing treatment, an annealing atmosphere is a mixed gas atmosphere of nitrogen and oxygen.

17. The method for manufacturing a semiconductor device according to claim 16, wherein
a ratio of a flow rate of the oxygen to a flow rate of the nitrogen is set to 1% or more.

18. The method for manufacturing a semiconductor device according to claim 1, wherein
the p-type impurity is Mg.

19. A semiconductor device comprising:
a first n-type layer comprising an n-type Group III nitride semiconductor,
a p-type layer formed over the first n-type layer and comprising a p-type Group III nitride semiconductor; and
a second n-type layer formed over the p-type layer and comprising an n-type Group III nitride semiconductor, wherein
an H concentration is 10% or less of a p-type impurity concentration in the p-type layer.

20. The semiconductor device according to claim 19, wherein
the p-type impurity concentration in the p-type layer is 1×10¹⁸/cm³ or more and 1×10²⁰/cm³ or less.
